(19) United States
(12) Patent Application Publication
(10) Pub. No.: US 2021/0142990 A1
(43) Pub. Date: May 13, 2021

(54) PLASMA PROCESSING APPARATUS

(71) Applicant: Tokyo Electron Limited, Tokyo (JP)

(72) Inventor: Masanori Asahara, Kurokawa-gum (JP)

(21) Appl. No.: 17/094,886

(22) Filed: Nov. 11, 2020

(30) Foreign Application Priority Data
Nov. 12, 2019 (JP) 2019-204978

(51) Int. Cl. H01J 37/32

(52) U.S. Cl. CPC H01J 37/32642; H01J 37/32715; H01J 2237/2007; H01J 2237/334; H01J 37/3244

(57) ABSTRACT

A plasma processing apparatus includes a placing table configured to place a substrate thereon; a chamber accommodating the placing table therein; a gas supply unit configured to supply a processing gas into the chamber; a plasma forming device configured to form plasma within the chamber; a consumption member which is disposed in a space in which the plasma is formed, and which is consumed by the plasma; and a controller. The consumption member includes a base member made of a material including an oxygen element; and a cover member made of a material which does not include the oxygen element. At least a part of a surface of the base member exposed to the space in which the plasma is formed is covered with the cover member.

### CROSS-REFERENCE TO RELATED APPLICATION

This application claims the benefit of Japanese Patent Application No. 2019-204978 filed on Nov. 12, 2019, the entire disclosure of which is incorporated herein by reference.

### TECHNICAL FIELD

The various aspects and embodiments described herein pertain generally to a plasma processing apparatus.

### BACKGROUND

There is known a plasma processing apparatus configured to perform a required processing on a substrate by supplying a processing gas into a chamber and producing plasma from the processing gas. In such a plasma processing, it takes time for the plasma processing to be stabilized due to consumption of members within the chamber and deposition of a reaction byproduct thereto.

Patent Document 1 describes a plasma processing apparatus having a vacuum processing vessel. The vacuum processing vessel is equipped with a sidewall member, a cover member and a dielectric plate, and a film including yttrium is formed on an inner surface of the sidewall member and on a peripheral portion of a surface of the dielectric plate at a sidewall member side.
Patent Document 1: Japanese Patent Laid-open Publication No. 2007-243020

### SUMMARY

In one exemplary embodiment, a plasma processing apparatus includes a placing table configured to place a substrate thereon; a chamber accommodating the placing table therein; a gas supply unit configured to supply a processing gas into the chamber; a plasma forming device configured to form plasma within the chamber; a consumption member which is disposed in a space in which the plasma is formed, and which is consumed by the plasma; and a controller. The consumption member includes a base member made of a material including an oxygen element; and a cover member made of a material which does not include the oxygen element. At least a part of a surface of the base member exposed to the space in which the plasma is formed is covered with the cover member.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a schematic cross sectional diagram illustrating an example of a plasma processing apparatus according to an exemplary embodiment;

FIG. 2A and FIG. 2B are partially enlarged views of the plasma processing apparatus according to the exemplary embodiment;

FIG. 3A and FIG. 3B are partially enlarged views of a plasma processing apparatus according to a reference example;

FIG. 4A and FIG. 4B present examples of a top view of a cover ring; and

FIG. 5A and FIG. 5B provide examples of a partially enlarged view of a plasma processing apparatus according to another exemplary embodiment.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, exemplary embodiments of the present disclosure will be described in detail with reference to the accompanying drawings. In the various drawing, like parts will be assigned like reference numerals, and redundant description will be omitted.

A plasma processing apparatus 1 according to an exemplary embodiment will be explained with reference to FIG. 1. FIG. 1 is a schematic cross sectional diagram illustrating an example of the plasma processing apparatus 1 according to the exemplary embodiment. In the following description, the plasma processing apparatus 1 is described as, for example, a plasma etching apparatus configured to etch an insulating film (a SiO₂ film, a SiN film, or the like) formed on a substrate W.

The plasma processing apparatus 1 is equipped with a chamber 10. The chamber 10 has an internal space 10s therein. The chamber 10 includes a chamber main body 12. The chamber main body 12 has a substantially cylindrical shape. The chamber main body 12 is made of, by way of example, but not limitation, aluminum. A corrosion-resistant film is provided on an inner wall surface of the chamber main body 12. This corrosion-resistant film may be made of ceramic such as aluminum oxide or yttrium oxide.

A passage 12p is formed at a sidewall of the chamber main body 12. The substrate W is transferred between the internal space 10s and an outside of the chamber 10 through the passage 12p. The passage 12p is opened or closed by a gate valve 12g which is provided along the sidewall of the chamber main body 12.

A supporting member 13 is provided on a bottom of the chamber main body 12. The supporting member 13 is made of an insulating material. The supporting member 13 has a substantially cylindrical shape. Within the internal space 10s, the supporting member 13 extends upwards from the bottom of the chamber main body 12. The supporting member 13 has a supporting table 14 at an upper portion thereof. The supporting table 14 is configured to support the substrate W within the internal space 10s.

The supporting table 14 has a lower electrode 18 and an electrostatic chuck 20. The supporting table 14 may be further equipped with an electrode plate 16. The electrode plate 16 is made of a conductor such as, but not limited to, aluminum and has a substantially disk shape. The lower electrode 18 is provided on the electrode plate 16. The lower electrode 18 is made of a conductor such as, but not limited to, aluminum and has a substantially disk shape. The lower electrode 18 is electrically connected with the electrode plate 16.

The electrostatic chuck 20 is provided on the lower electrode 18. The substrate W is placed on a top surface of the electrostatic chuck 20. The electrostatic chuck 20 includes a main body and an electrode. The main body of the electrostatic chuck 20 has a substantially disk shape and is formed of a dielectric material. The electrode of the electrostatic chuck 20 is a film-shaped electrode and provided within the main body of the electrostatic chuck 20. The electrode of the electrostatic chuck 20 is connected to a DC power supply 20p via a switch 20s. If a voltage is applied to the electrode of the electrostatic chuck 20 from the DC power supply 20p, an electrostatic attracting force is generated between the electrostatic chuck 20 and the substrate W. The substrate W is held by the electrostatic chuck 20 by the generated electrostatic attracting force.

An edge ring 25 is provided on a peripheral portion of the lower electrode 18 to surround an edge of the substrate W. This edge ring 25 is configured to improve in-surface uniformity of a plasma processing upon the substrate W. The edge ring 25 may be made of, but not limited to, silicon, silicon carbide or quartz.

Further, a cover ring 26 is disposed around the edge ring 25 to surround it. The cover ring 26 is made of an insulator such as, but not limited to, quartz. The cover ring 26 protects a top surface of the supporting member 13 and a sidewall of the lower electrode 18 from plasma. The cover ring 26 is replaceable.

A path 18f is formed within the lower electrode 18. A heat exchange medium (for example, a coolant) is supplied into the path 18f via a pipeline 22a from a chiller unit (not shown) provided at an outside of the chamber 10. The heat exchange medium supplied into the path 18f is returned back into the chiller unit via a pipeline 22b. In the plasma processing apparatus 1, a temperature of the substrate W placed on the electrostatic chuck 20 is adjusted by a heat exchange between the heat exchange medium and the lower electrode 18.

The plasma processing apparatus 1 is equipped with a gas supply line 24. A heat transfer gas (e.g., a He gas) from a heat transfer gas supply mechanism is supplied into a gap between the top surface of the electrostatic chuck 20 and a rear surface of the substrate W through the gas supply line 24.

The plasma processing apparatus 1 is further equipped with an upper electrode 30. The upper electrode 30 is provided above the supporting table 14. The upper electrode 30 is supported at an upper portion of the chamber main body 12 with members 32 and 33 therebetween. The members 32 and 33 are made of a material having insulation property. The upper electrode 30 and the members 32 and 33 close a top opening of the chamber main body 12. The member 33 is disposed around a ceiling plate 34 to surround the ceiling plate 34. The member 33 is exposed to the internal space 10s, and is made of an insulator such as, but not limited to, quartz. By designing the member 32 and the member 33 as separate parts, the member 33 which is worn away by the plasma can be replaced.

The upper electrode 30 may include the ceiling plate 34 and a supporting body 36. A bottom surface of the ceiling plate 34 is a surface facing the internal space 10s, and it forms and confines the internal space 10s. The ceiling plate 34 may be formed of a low-resistance conductor or semiconductor having low Joule's heat. The ceiling plate 34 is provided with multiple gas discharge holes 34a which are formed through the ceiling plate 34 in a plate thickness direction.

The supporting body 36 is configured to support the ceiling plate 34 in a detachable manner. The supporting body 36 is made of a conductive material such as, but not limited to, aluminum. A gas diffusion space 36a is provided within the supporting body 36. The supporting body 36 is provided with multiple gas holes 36b which extend downwards from the gas diffusion space 36a. The multiple gas holes 36b respectively communicate with the multiple gas discharge holes 34a. Further, the supporting body 36 is provided with a gas inlet opening 36c. The gas inlet opening 36c is connected to the gas diffusion space 36a. A gas supply line 38 is connected to this gas inlet opening 36c.

A valve group 42, a flow rate controller group 44 and a gas source group 40 are connected to the gas supply line 38. The gas source group 40, the valve group 42 and the flow rate controller group 44 constitute a gas supply unit. The gas source group 40 includes a plurality of gas sources. The valve group 42 includes a plurality of opening/closing valves. The flow rate controller group 44 includes a plurality of flow rate controllers. Each of the flow rate controllers belonging to the flow rate controller group 44 may be a mass flow controller or a pressure control type flow rate controller. Each of the gas sources belonging to the gas source group 40 is connected to the gas supply line 38 via a corresponding opening/closing valve belonging to the valve group 42 and a corresponding flow rate controller belonging to the flow rate controller group 44.

In the plasma processing apparatus 1, a shield 46 is provided along the inner wall surface of the chamber main body 12 and an outer side surface of the supporting member 13 in a detachable manner. Accordingly, the shield 46 can be replaced. The shield 46 is configured to suppress an etching byproduct from adhering to the chamber main body 12. The shield 46 may be made of, by way of non-limiting example, an aluminum base member having a corrosion-resistant film formed on a surface (inner circumferential surface) thereof. The corrosion-resistant film may be made of ceramic such as yttrium oxide or alumite.

A baffle plate 48 is provided between the supporting member 13 and the sidewall of the chamber main body 12. The baffle plate 48 may be made of, by way of example, an aluminum base member having a corrosion-resistant film (an yttrium oxide film or the like) formed on a surface thereof. The baffle plate 48 is provided with a plurality of through holes. A gas exhaust port 12e is provided at the bottom of the chamber main body 12 under the baffle plate 48. The gas exhaust port 12e is connected with a gas exhaust device 50 via a gas exhaust line 52. The gas exhaust device 50 has a pressure control valve and a vacuum pump such as a turbo molecular pump.

The plasma processing apparatus 1 is further equipped with a first high frequency power supply 62 and a second high frequency power supply 64. The first high frequency power supply 62 is configured to generate a first high frequency power. The first high frequency power has a frequency suitable for plasma formation. The frequency of the first high frequency power is in a range from, e.g., 27 MHz to 100 MHz. The first high frequency power supply 62 is connected to the lower electrode 18 via a matching device 66 and the electrode plate 16. The matching device 66 is equipped with a circuit configured to match an output impedance of the first high frequency power supply 62 and an impedance at a load side (lower electrode 18 side). Further, the first high frequency power supply 62 may be connected to the upper electrode 30 via the matching device 66. The first high frequency power supply 62 constitutes an example plasma forming device.

The second high frequency power supply 64 is configured to generate a second high frequency power. A frequency of the second high frequency power is lower than the frequency of the first high frequency power. When the first high frequency power and the second high frequency power are used together, the second high frequency power is used as a high frequency bias power for ion attraction into the substrate W. The frequency of the second high frequency power falls within a range from, e.g., 400 kHz to 13.56 MHz. The second high frequency power supply 64 is connected to the lower electrode 18 via a matching device 68 and the electrode plate 16. The matching device 68 is equipped with a circuit configured to match an output impedance of the second high frequency power supply 64 and the impedance at the load side (lower electrode 18 side).

Here, plasma may be formed by using only the second high frequency power without using the first high frequency power, that is, by using a single high frequency power. In such a case, the frequency of the second high frequency power may be larger than 13.56 MHZ, for example, 40 MHz. The plasma processing apparatus 1 may not be equipped with the first high frequency power supply 62 and the matching device 66. The second high frequency power supply 64 constitutes the example plasma forming device.

In the plasma processing apparatus 1, a gas is supplied from the gas supply unit into the internal space 10s to form the plasma. Further, by supplying the first high frequency power and/or the second high frequency power, a high frequency electric field is formed between the upper electrode 30 and the lower electrode 18. The generated high frequency electric field forms the plasma.

The plasma processing apparatus 1 is equipped with a power supply 70. The power supply 70 is connected to the upper electrode 30. The power supply 70 applies to the upper electrode 30 a voltage for attracting positive ions existing in the internal space 10s into the ceiling plate 34.

The plasma processing apparatus 1 may be further equipped with a controller 80. The controller 80 may be a computer including a processor, a storage such as a memory, an input device, a display device, a signal input/output interface, and so forth. The controller 80 controls the individual components of the plasma processing apparatus 1. In the controller 80, a command or the like may be inputted by an operator through the input device to manage the plasma processing apparatus 1. Further, in the controller 80, an operational status of the plasma processing apparatus 1 can be visually displayed by the display device. Furthermore, control programs and recipe data are stored in the storage of the controller 80. The control programs are executed by the processor of the controller 80 to allow various processings to be performed in the plasma processing apparatus 1. The processor executes the control programs and controls the individual components of the plasma processing apparatus 1 according to the recipe data.

An example of an operation of the plasma processing apparatus 1 will be explained. An insulating film (a SiO₂ film, a SiN film, or the like) is formed on the substrate Was an etching target film. Further, a mask having an opening is formed on the insulating film.

The controller 80 controls the gas source group 40, the valve group 42 and the flow rate controller group 44 to supply an etching gas and an argon gas into the internal space 10s from the gas holes 36b. Fluorocarbon, hydrofluorocarbon, or the like is used as the etching gas. The fluorocarbon may be, by way of non-limiting example, CF₄, C₄F₆, or C₄F₈, and the hydrofluorocarbon may be, by way of non-limiting example, CHF₃ or CH₂F₂. Further, the controller 80 controls the first high frequency power supply 62 to apply the first high frequency power for plasma formation to the lower electrode 18. Further, the controller 80 controls the second high frequency power supply 64 to apply to the lower electrode 18 the second high frequency power for ion attraction into the substrate W.

Accordingly, the insulating film is etched through the mask by plasma formed in the internal space 10s. Further, the edge ring 25, the cover ring 26, the member 33, the shield 46, and so forth are consumed by the plasma formed in the internal space 10s.

Further, when the insulating film is etched, a reaction byproduct is produced. The reaction byproduct may be, by way of non-limiting example, fluorocarbon or hydrocarbon. The reaction byproduct is exhausted from the internal space 10s by the gas exhaust device 50. Further, a part of the reaction byproduct adheres to the edge ring 25, the cover ring 26, the member 33, the shield 46, and so forth.

Now, the plasma processing apparatus 1 according to the present exemplary embodiment will be further discussed with reference to FIG. 2A and FIG. 2B. FIG. 2A and FIG. 2B present examples of a partially enlarged view of the plasma processing apparatus 1 according to the present exemplary embodiment. FIG. 2A illustrates an initial state immediately after the cover ring 26 is replaced through maintenance or the like. FIG. 2B illustrates a state in which the cover ring 26 is consumed with a lapse of time and a reaction byproduct 200 is attached thereto.

As depicted in FIG. 1 and FIG. 2A and FIG. 2B, the substrate W is placed on the supporting table 14, specifically, on the electrostatic chuck 20 provided on the lower electrode 18. The edge ring 25 configured to improve in-surface uniformity of a plasm processing upon the substrate W is disposed on the lower electrode 18 to surround the edge of the substrate W. The cover ring 26 which protects the top surface of the supporting member 13 (see FIG. 1) and the sidewall of the lower electrode 18 is disposed around the edge ring 25 to surround it.

Further, in FIG. 2A and FIG. 2B, a region where the plasma is formed is schematically indicated by a dashed line. When the insulating film of the substrate W is etched by the plasma processing, the reaction byproduct 200 is produced. A part of the reaction byproduct adheres to the cover ring 26 or the like. Here, a region 301 close to the plasma formation region is a region in which an etching rate of the reaction byproduct 200 attached on a surface of the cover ring 26 is higher than a deposition rate of the reaction byproduct 200. On the surface of the cover ring 26 within the region 301, the attached reaction byproduct 200 is etched by the plasma, so that the surface of the cover ring 26 is kept exposed. Further, a region 302 at an outer side than the region 301 is a region in which an etching rate of the reaction byproduct 200 attached on the surface of the cover ring 26 is lower than a deposition rate of the reaction byproduct 200. On the surface of the cover ring 26 within the region 302, the surface of the cover ring 26 gets covered with the reaction byproduct 200, as illustrated in FIG. 2B.

As shown in FIG. 2A, the cover ring 26 includes a base member 110 and a cover member 120.

The base member 110 is a circular ring-shaped member and is made of a material including an element that affects a processing characteristic, specifically, a material (e.g., SiO₂) including an oxygen element (O). In the example of FIG. 2A, the base member 110 has a top surface 111 facing the plasma formation region, an inclined surface 112 distanced farther from the plasma formation region than the top surface 111, and an outer side surface 113 distanced farther from the plasma formation region than the inclined surface 112.

The cover member 120 is made of a material not including an element which affects the processing characteristic, specifically, an oxygen element (O). Further, the cover member 120 is made of the same material as the reaction byproduct produced by a process performed by the plasma processing apparatus 1. Here, in a process in which fluorocarbon is generated as the reaction byproduct by using the fluorocarbon-based gas (CF₄, C₄F₆, C₄F₈, or the like) as the etching gas, the cover member 120 is made of a material including a carbon element (C) and a fluorine element (F). Further, the reaction byproduct and the cover member 120 only need to be composed of the same element, and compounds including that same element may not always be identical between them. In the present exemplary embodiment, a fluorine resin such as PTFE (polytetrafluoroethylene) or PCTFE (polychlorotrifluoroethylene) may be used as the material of the cover member 120.

Further, it is desirable that the material of the cover member 120 is selected such that a consumption amount of this material by the plasma is larger than a consumption amount of the material (for example, SiO₂) of the base member 110 by the plasma. That is, it is desirable that the cover member 120 is made of a material having low plasma resistance than that of the base member 110.

The cover member 120 is formed to cover the inclined surface 112 and the outer side surface 113. Further, the cover member 120 may be formed to cover a part of the top surface 111 while leaving the rest of the top surface 111 exposed. Further, the cover member 120 may be formed to cover a part of the inclined surface 112 while leaving the rest of the inclined surface 112 exposed.

Furthermore, the cover member 120 may be designed as a component part and assembled to the base member 110 to form the cover ring 26. Further, the cover member 120 may be a coating film which is formed by coating and hardening a fluorine resin in the form of a slurry on the base member 110. The way how to form the cover member 120 is not limited to the mentioned examples.

Here, the plasma processing apparatus 1 according to the present exemplary embodiment will be further explained in comparison with a plasma processing apparatus of a reference example.

FIG. 3A and FIG. 3B present examples of a partially enlarged view of the plasma processing apparatus according to the reference example. FIG. 3A illustrates an initial state immediately after a cover ring 26C is replaced through maintenance or the like. FIG. 3B shows a state in which the cover ring 26C is consumed with a lapse of time and a reaction byproduct 200 is attached thereto.

The plasma processing apparatus (see FIG. 3A and FIG. 3B) of the reference example is different from the plasma processing apparatus (see FIG. 2A and FIG. 2B) of the present exemplary embodiment in terms of the cover ring 26C. Other configurations of the plasma processing apparatus of the reference example are the same as those of the plasma processing apparatus 1 of the present exemplary embodiment, so redundant description will be omitted. As depicted in FIG. 3A, the cover ring 26C is different from the cover ring 26 in that it does not have a cover member 120. That is, the cover ring 26C is a circular ring-shaped member and is made of a material (for example, SiO₂) including oxygen (O). In the example of FIG. 3A, the cover ring 26C has a top surface 111 facing a plasma formation region, an inclined surface 112 distanced farther from the plasma formation region than the top surface 111, and an outer side surface 113 distanced farther from the plasma formation region than the inclined surface 112.

In the initial state of the plasma processing apparatus according to the reference example, the top surface 111, the inclined surface 112 and the outer side surface 113 are exposed to an internal space 10s, as depicted in FIG. 3A. Therefore, when an etching processing is performed on a substrate W, the top surface 111 and the inclined surface 112 of the cover ring 26C exposed to plasma are consumed, so that oxygen radicals O* are generated from the cover ring 26C. That is, in the initial state, the oxygen radicals O* are generated from a surface (the top surface 111) of the cover ring 26C within a region 301 and a surface (inclined surface 112) of the cover ring 26C within a region 302. The oxygen radicals O* generated when the cover ring 26C is consumed affect an etching characteristic of the substrate W.

FIG. 3B illustrates an example of a state in which a generation amount of the oxygen radicals O* is stabilized with a lapse of time. As shown in FIG. 3B, the two regions 301 and 302 are distinguished based on whether an etching rate of the reaction byproduct 200 or a deposition rate of the reaction byproduct 200 is larger.

The region 301 close to the plasma formation region is a region where the etching rate of the reaction byproduct 200 attached on the surface of the cover ring 26C is higher than the deposition rate of this reaction byproduct 200. In the region 301, the cover ring 26C is exposed, and the oxygen radicals O* are generated as the cover ring 26C is exposed to the plasma.

The region 302 at an outer side than the region 301 is a region where the etching rate of the reaction byproduct 200 attached on the surface of the cover ring 26C is lower than the deposition rate of the reaction byproduct 200. The reaction byproduct 200 adheres to the region 302, so that the cover ring 26C is covered with the reaction byproduct 200. For the reason, generation of the oxygen radicals O* from the region 302 is suppressed. Further, as the reaction byproduct 200 adheres to the region 302 to cover the cover ring 26C, the generation amount of the oxygen radicals O* from the cover ring 26C is stabilized.

As stated above, in the plasma processing apparatus according to the reference example, the generation amount of the oxygen radicals O* which affect the etching characteristic of the substrate W changes (decreases) from the initial state (see FIG. 3A) to the stabilized state (see FIG. 3B) with the lapse of the time. As a result, the etching characteristic of the substrate W varies over a period ranging from the initial state to the stabilized state.

In contrast, in the initial state of the plasma processing apparatus 1 according to the present exemplary embodiment, the top surface 111 of the base member 110 is exposed to the internal space 10s, whereas the inclined surface 112 and the outer side surface 113 are covered with the cover member 120, as shown in FIG. 2A. Therefore, when the etching processing is performed on the substrate W, the top surface 11 of the base member 110 exposed to the plasma is consumed, so that oxygen radicals O* are generated from the base member 110. Meanwhile, since the inclined surface 112 and the outer side surface 113 of the base member 110 are covered with the cover member 120, generation of oxygen radicals O* from the inclined surface 112 and the outer side surface 113 is suppressed. That is, in the initial state, the oxygen radicals O* are generated from the surface (top surface 111) of the cover ring 26 within the region 301, and generation of the oxygen radicals O* from the surface (inclined surface 112 and the outer side surface 113) of the cover ring 26 within the region 302 is suppressed.

As illustrated in FIG. 2B, the two regions 301 and 302 are distinguished based on whether the etching rate of the reaction byproduct 200 or the deposition rate of the reaction byproduct 200 is larger.

In the region 301 where the etching rate is higher than the deposition rate, the base member 110 is exposed. Thus, as the base member 110 is exposed to the plasma, the oxygen radicals O* are generated.

In the region 302 where the etching rate is lower than the deposition rate, the reaction byproduct 200 adheres to the surface of the cover member 120. Accordingly, the base member 110 is covered with the cover member 120 and/or the reaction byproduct 200. Thus, generation of oxygen radicals O* from the region 302 is suppressed. Further, since the reaction byproduct 200 adheres to the region 302 to cover the cover ring 26, a generation amount of the oxygen radicals O* from the cover ring 26 is stabilized.

According to the present exemplary embodiment, the generation amount of the oxygen radicals O* in the initial state is reduced to become approximate to the generation amount of the oxygen radicals O* in the stabilized state. Further, a time taken before the generation amount of the oxygen radicals O* is stabilized can be shortened.

Furthermore, in the cover ring 26 in the initial state, it is desirable that the base member 110 within the region 301 is exposed. However, at least a part of the base member 110 within the region 301 may be covered with the cover member 120. The cover member 120 within the region 301 is rapidly consumed by the plasma, rendering the base member 110 exposed. If the base member 110, which is exposed due to the consumption of the cover member 120, is exposed to the plasma, oxygen radicals O* are generated from this base member 110 as well. Further, as the cover member 120 within the region 301 is consumed, the generation amount of the oxygen radicals O* from the cover ring 26 is stabilized.

Additionally, the region 301 where the etching rate is higher than the deposition rate and the region 302 where the etching rate is lower than the deposition rate may be differed depending on the plasma processing apparatuses 1 involved (that is, there may exist a difference between apparatuses) and processing conditions. In the plasma processing apparatus 1 of the present exemplary embodiment, since the cover member 120 within the region 301 is rapidly consumed, the time required for the generation amount of the oxygen radicals O* to be stabilized can be reduced.

Further, the cover member 120 may be formed in the region 302 and a region near a boundary between the region 301 and the region 302. That is, the cover member 120 is not formed in a range which will obviously be the region 301, and the base member 110 is exposed in this range. Further, in a range which will obviously be the region 302, the cover member 120 is formed. Furthermore, in a range near the boundary for which it cannot be said definitely whether it will be the region 301 or the region 302, the cover member 120 is formed. Accordingly, fluctuation in the generation amount of the oxygen radicals O* in a period ranging from the initial state to the stabilized state can be suppressed. Further, the time taken before the generation amount of the oxygen radicals O* is stabilized can be shortened. Moreover, a position where the cover member 120 is formed need not be changed for each of different plasma processing apparatuses 1 and for each of different processing conditions. Therefore, a manufacturing cost for the cover ring 26 can be reduced.

Moreover, since the cover member 120 is formed of the material having the same element as that of the reaction byproduct 200, an influence upon the processing characteristic can be suppressed when the cover member 120 is consumed by the plasma. In addition, since the cover member 120 is formed of the material which does not include the oxygen element (O), an influence upon the processing characteristic can be suppressed.

FIG. 4A and FIG. 4B present examples of a top view of the cover ring 26. In FIG. 4A and FIG. 4B, a region covered with the cover member 120 is indicated by using a dotted pattern.

The cover ring 26 is equipped with the base member 110 having the top surface 11 formed at an inner side and the inclined surface 112 formed at an outer side; and the cover member 120 which covers a part of the surface of the base member 110.

Here, in the plasma processing apparatus 1 shown in FIG. 1, the reaction byproduct produced when the insulating film of the substrate W is etched is exhausted by the gas exhaust device 50 from the internal space 10s through the gas exhaust port 12e. As a result, the deposition rate of the reaction byproduct is not symmetrical in a circumferential direction of the cover ring 26, and the deposition rate is higher near the gas exhaust port 12e. That is, the region 301 (see FIG. 2A and FIG. 2B) and the region 302 (see FIG. 2A and FIG. 2B) may not be symmetrical in the circumferential direction of the cover ring 26. In FIG. 4A and FIG. 4B, it is assumed that the gas exhaust port 12e is provided at a left bottom side, when viewed from a center of the cover ring 26. As shown in FIG. 4A, the region covered with the cover member 120 may be eccentrically arranged. Further, as shown in FIG. 4B, an area covered with the cover member 120 may be differed in the circumferential direction. With these configurations, the range where the cover member 120 is formed can be changed in view of asymmetricity of the regions 301 and 302, so that fluctuation in the generation amount of the oxygen radicals O* in the period ranging from the initial state to the stabilized state can be suppressed. Further, the time taken before the generation amount of the oxygen radicals O* is stabilized can be shortened.

Furthermore, though the above exemplary embodiment has been described for the example configuration where a part of the surface of the base member 110 of the cover ring 26 exposed to the internal space 10s is covered with the cover member 120, the present exemplary embodiment is not limited thereto. FIG. 5A and FIG. 5B are examples of a partially enlarged view of a plasma processing apparatus 1 according to another exemplary embodiment.

As depicted in FIG. 5A, as for a member 33 disposed in an upper portion of an internal space 10s, a part of a surface of this member 33 exposed to the internal space 10s may be covered with a cover member 140. That is, the member 33 has a base member 130 and a cover member 140.

The base member 130 is a circular ring-shaped member disposed to surround a ceiling plate 34 and is made of a material (for example, SiO₂) including an element which affects a processing characteristic, specifically, an oxygen element (O).

Like the cover member 120 (see FIG. 2A and FIG. 2B), the cover member 140 is made of a material which does not include the element having an influence upon the processing characteristic, specifically, the oxygen element (O). The cover member 140 is made of the same material as a reaction byproduct which is produced by a process performed by the plasma processing apparatus 1. Furthermore, it is desirable that the material of the cover member 140 is selected such that a consumption amount of this material by plasma is larger than a consumption amount of the material (for example, SiO₂) of the base member 130 by the plasma. That is, it is desirable that the cover member 140 is made of a material having low plasma resistance than that of the base member 130.

The cover member 140 is formed to cover a part of a surface of the base member 130 exposed to the internal space 10s. For example, the cover member 140 is formed in a region (for example, at an outer peripheral side of the base member 130) where an etching rate is lower than a deposition rate.

Furthermore, as depicted in FIG. 5B, parts of a surface of a shied 46 which are exposed to the internal space 10s may be covered with cover members 161 and 162. That is, the shield 46 includes a base member 150 and the cover members 161 and 162.

As stated above, an inner circumferential surface of the base member 150 of the shield 46 is covered with, by way of non-limiting example, an alumite layer or an yttrium oxide film. The alumite layer or the yttrium oxide film is slightly consumed as they are exposed to plasma, resulting in generation of oxygen radicals O*.

Like the cover member 120 (see FIG. 2A and FIG. 2B), the cover members 161 and 162 are made of a material without containing the element which affects the processing characteristic, specifically, the oxygen element (O). Further, the cover members 161 and 162 are made of the same material as the reaction byproduct which is produced by the process performed by the plasma processing apparatus 1. Furthermore, it is desirable that the material of the cover members 161 and 162 is selected such that a consumption amount of this material by the plasma is larger than a consumption amount of a material of the base member 150 by the plasma. That is, it is desirable that the cover members 161 and 162 are made of a material having low plasma resistance than that of the base member 150.

The cover members 161 and 162 are formed to cover a part of a surface of the base member 150 exposed to the internal space 10s. For example, the cover member 161 is formed in a region (for example, on a top surface of the base member 150) where an etching rate is lower than a deposition rate because the plasma has difficulty in reaching there. By way of example, the cover member 162 is formed in a region (for example, on a sidewall of the base member 150 near a baffle plate 48) where a deposition rate in a path from the internal space 10s to an exhaust port 12e (see FIG. 1) is increased.

With this configuration, in the members (the member 33, the shield 46, and so forth) disposed in the internal space 10s as well as in the cover ring 26, a generation amount of the oxygen radicals O* in an initial state can be reduced to become approximate to a generation amount of the oxygen radicals O* in a stabilized state. Further, a time taken before the generation amount of the oxygen radicals O* is stabilized can be shortened.

So far, the exemplary embodiments of the plasma processing apparatus 1 have been described. However, it should be noted that the present disclosure is not limited to the above-described exemplary embodiments, and various changes and modification may be made within the scope of the present disclosure described in the claims.

According to the exemplary embodiment, it is possible to provide the plasma processing apparatus capable of reducing a time required for a processing to be stabilized when the consumable member is replaced.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. A plasma processing apparatus, comprising:
a placing table configured to place a substrate thereon;
a chamber accommodating the placing table therein;
a gas supply unit configured to supply a processing gas into the chamber;
a plasma forming device configured to form plasma within the chamber;
a consumption member which is disposed in a space in which the plasma is formed, and which is consumed by the plasma; and
a controller,
wherein the consumption member comprises:
a base member made of a material including an oxygen element; and
a cover member made of a material which does not include the oxygen element, and
wherein at least a part of a surface of the base member exposed to the space in which the plasma is formed is covered with the cover member.

2. The plasma processing apparatus of claim 1,
wherein the material of the cover member has lower plasma resistance than the material of the base member.

3. The plasma processing apparatus of claim 1,
wherein the material of the cover member includes an element same as a reaction byproduct produced when a plasma processing is performed on the substrate.

4. The plasma processing apparatus of claim 3,
wherein the material of the cover member includes a carbon element and a fluorine element.

5. The plasma processing apparatus of claim 1,
wherein the consumption member comprises:
a first region where an etching rate of a reaction byproduct, which is produced when a plasma processing is performed on the substrate, is higher than a deposition rate of the reaction byproduct; and
a second region where the etching rate of the reaction byproduct is lower than the deposition rate of the reaction byproduct, and
wherein at least a part of the base member is exposed in the first region.

6. The plasma processing apparatus of claim 5,
wherein the base member is covered with the cover member in the second region.

7. The plasma processing apparatus of claim 1,
wherein a plasma processing with the plasma is etching a silicon-containing film formed on the substrate.

8. The plasma processing apparatus of claim 1,
wherein the base member of the consumption member is made of SiO₂, and
the consumption member is a circular ring-shaped member disposed around the substrate.

9. The plasma processing apparatus of claim 1,
wherein the base member of the consumption member is made of SiO₂, and
the consumption member is a circular ring-shaped member disposed above the placing table.

10. The plasma processing apparatus of claim 1,
wherein the base member of the consumption member is covered with an oxide film, and
the consumption member is a shield disposed on an outer side surface of the placing table and an inner circumferential surface of the chamber.
